(19) United States
(12) Patent Application Publication
(10) Pub. No.: US 2010/0065918 A1
(43) Pub. Date: Mar. 18, 2010

(54) SEMICONDUCTOR DEVICE AND METHOD FOR MANUFACTURING THE SAME

(76) Inventors: Daisuke Ikeno, Yokohama-shi (JP); Tomonori Aoyama, Yokohama-shi (JP); Kazuaki Nakajima, Tokyo (JP); Seiji Inumiya, Yokohama-shi (JP); Takashi Shimizu, Yokohama-shi (JP); Takuya Kobayashi, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/561,862

(22) Filed: Sep. 17, 2009

(30) Foreign Application Priority Data
Sep. 18, 2008 (JP) P2008-239200

(51) Int. Cl. H01L 27/092; H01L 21/8238

(52) U.S. Cl. 257/369; 438/218; 257/E27.062; 257/E21.632

(57) ABSTRACT

A semiconductor device includes a semiconductor substrate containing a p-type diffusion layer and an n-type diffusion layer which are separated by an element separation film; a gate insulating film formed on or above the p-type diffusion layer and the n-type diffusion layer of the semiconductor substrate, respectively; a gate electrode containing a metallic film and formed on the gate insulating film; a Ge inclusion formed at an interface between the gate insulating film and the metallic film; and a silicon-containing layer formed on the metallic film.

### CROSS-REFERENCE TO RELATED APPLICATIONS

This application is based upon and claims the benefit of priority from the prior Japanese Patent Application No. 2008-239200 filed on Sep. 18, 2008; the entire contents which are incorporated herein by reference.

### BACKGROUND OF THE INVENTION

1. Field of the Invention

The present invention relates to a semiconductor device and a method for manufacturing a semiconductor device.

2. Description of the Related Art

With the miniaturization of a large scale integrated circuit (LSI), it is required that the gate insulating film is thinned. Ina CMOS (Complementary Metal Oxide Semiconductor) of 32 nm node level, it is required that the gate insulating film has an insulating property of a thickness of 0.9 nm or less as equivalent SiO₂ thickness. In a polysilicon electrode which would be employed as a conventional gate electrode, however, since the polysilicon gate electrode is depleted due to the inherent semiconductor properties, the thickness of the gate insulating film to be employed must be increased by about 0.3 nm, resulting in the disturbance of the thinning of the gate insulating film.

In order to inhibit the gate depletion of the polysilicon gate electrode, therefore, the introduction of a metal gate electrode is desired. It is required that the metal gate electrode has an effective work function (EWF) around Si band edge in order to reduce the threshold value (Vth) of the transistor. Concretely, in an NMOSFET (N Channel Metal Oxide Semiconductor Field Effect Transistor), it is required that the metal gate electrode has an effective work function around the Si conduction band edge (4.05 eV). In a PMOSFET (P Channel Metal Oxide Semiconductor Field Effect Transistor), moreover, it is required that the metal gate electrode has an effective work function around the Si valence band edge (5.17 eV). By realizing the effective work function around the Si band edge, the threshold voltage (Vth) of the transistor is reduced so that the CMOS can exhibit the inherent performances.

At present, on the other hand, the gate electrode is configured as a stacking structure of polysilicon layer/metal layer while a nickel silicide is formed on the polysilicon layer to reduce the contact resistance for the metal layer. Moreover, single metal gate technique is applied so that the material making the metal gate of the NMOSFET can be the same as the material making the metal gate of the PMOSFET.

Therefore, if the effective work function is set around the Si conduction band (4.05 eV), the threshold voltage of the PMOSFET is increased. In contrast, if the effective work function is set around the Si valence band (5.17 eV), the threshold voltage of the NMOSFET is increased.

In the single metal gate technique, in this point of view, supposed that a gate electrode material with an effective work function (EWF) around the mid-gap state of the silicon bandgap is used, various approaches are proposed in order to reduce the threshold voltages of the NMOSFET and the PMOSFET.

For example, an La₂O₃ (Lanthanum oxide) is applied for the NMOSFET so as to reduce the threshold voltage thereof. Moreover, an SiGe (silicon germanium) and an Al₂O₃ (aluminum oxide) are applied for the PMOSFET so as to reduce the threshold voltage thereof (refer to References 1 to 4). Practically, if the La₂O₃ is added at the interface between the insulating film and the Si substrate of the NMOSFET, the effective work function of the NMOSFET can be decreased by about 0.5 V so that the effective work function of the NMOSFET can be approximated to the Si conduction band edge (4.05 eV).

[Reference 1] Band-Edge High-Performance High-k/Metal Gate n-MOSFETs using Cap Layers Containing Group IIA and IIIB Elements with Gate-First Processing for 45 nm Beyond, V. Narayanan et al., Dig. Symp. VLSI Technology, 2006

[Reference 2] Achieving Conduction Band-Edge Effective Work Functions by La₂O₃ Capping of Hafnium Silicates L-A. Ragnarsson et al., IEEE Electron Device Lett. 28 (2007)486

[Reference 3] Dual High-k Gate Dielectric Technology Using Selective AlOx Etch (SAE) Process with Nitrogen and Fluorine Incorporation, H-S. Jung et al., Dig. Symp. VLSI Technology, 2006

[Reference 4] Highly Manufacturing 45 nm LSTP CMOSFETs Using Novel Dual High-k and Dual Metal Gate CMOS Integration, B. C. Ju et al., Dig. Symp. VLSI Technology, 2006

Furthermore, if the channel portion of the PMOSFET is made of SiGe and the Al₂O₃ is added to the interface between the insulating film and the Si substrate thereof, the threshold voltage of the PMOSFET can be increased by about 0.5 V so that the effective work function of the PMOSFET can be approximated to the Si valence band edge (5.17 eV). As a result, with the single metal gate technique, the threshold voltage of the intended CMOS can be reduced.

However, even though an appropriate gate electrode material is selected to set the initial effective work function to the state in the vicinity of the mid-gap state of the Si bandgap, the initial effective work function may be decreased from the state by about 0.2 eV if the gate electrode is configured as the stacking structure of polysilicon layer/metal layer and the siliciding process for the polysilicon layer is conducted. Therefore, even though the SiGe (silicon germanium) and the Al₂O₃ (aluminum oxide) are applied for the PMOSFET, the effective work function cannot be set to the state in the vicinity of the Si valence band edge so as not to reduce the threshold voltage of the PMOSFET as desired.

### BRIEF SUMMARY OF THE INVENTION

An aspect of the present invention relates to a semiconductor device, including: a semiconductor substrate containing a p-type diffusion layer and an n-type diffusion layer which are separated by an element separation film; a gate insulating film formed on or above the p-type diffusion layer and the n-type diffusion layer of the semiconductor substrate, respectively; a gate electrode containing a metallic film and formed on the gate insulating film; a Ge inclusion formed at an interface between the gate insulating film and the metallic film; and a silicon-containing layer formed on the metallic film.

Another aspect of the present invention relates to a method for manufacturing a semiconductor device, including: forming an element separation film in a semiconductor substrate such that a p-type diffusion layer is formed at one side of the semiconductor substrate from the element separation film thereof and an n-type diffusion layer is formed at the other side of the semiconductor substrate from the element separation film thereof; forming a gate insulating film on or above the p-type diffusion layer and the n-type diffusion layer of the semiconductor substrate, respectively; forming a gate electrode containing a metallic film on the gate insulating film; forming a Ge layer on the metallic film such that elemental Ge of the Ge layer is diffused to an interface between the gate insulating film and the metallic film through thermal treatment to form a Ge inclusion at the interface therebetween; and forming a silicon-containing layer on the metallic film.

Still another aspect of the present invention relates to a method for manufacturing a semiconductor device, including: forming an element separation film in a semiconductor substrate such that a p-type diffusion layer is formed at one side of the semiconductor substrate from the element separation film thereof and an n-type diffusion layer is formed at the other side of the semiconductor substrate from the element separation film thereof; forming a gate insulating film on or above the p-type diffusion layer and the n-type diffusion layer of the semiconductor substrate, respectively; forming a gate electrode containing a metallic film on the gate insulating film; forming a polysilicon layer on the metallic layer; injecting Ge ions into the polysilicon layer such that a Ge inclusion is formed at an interface between the gate insulating film and the metallic film; and forming a silicon-containing layer on the metallic film.

### BRIEF DESCRIPTION OF THE DRAWINGS

FIG. 1 is a cross sectional view showing a step in the manufacturing method of a semiconductor device according to a first embodiment.

FIG. 2 is also a cross sectional view showing a step in the manufacturing method of a semiconductor device according to the first embodiment.

FIG. 3 is also a cross sectional view showing a step in the manufacturing method of a semiconductor device according to the first embodiment.

FIG. 4 is also a cross sectional view showing a step in the manufacturing method of a semiconductor device according to the first embodiment.

FIG. 5 is also a cross sectional view showing a step in the manufacturing method of a semiconductor device according to the first embodiment.

FIG. 6 is also a cross sectional view showing a step in the manufacturing method of a semiconductor device according to the first embodiment.

FIG. 7 is also a cross sectional view showing a step in the manufacturing method of a semiconductor device according to the first embodiment.

FIG. 8 is also a cross sectional view showing a step in the manufacturing method of a semiconductor device according to the first embodiment.

FIG. 9 is a cross sectional view showing a step in the manufacturing method of a semiconductor device according to a second embodiment.

FIG. 10 is also a cross sectional view showing a step in the manufacturing method of a semiconductor device according to a second embodiment.

FIG. 11 is a graph showing the RBS (Rutherford back scattering) result in Example.

### DETAILED DESCRIPTION OF THE INVENTION

### First Embodiment

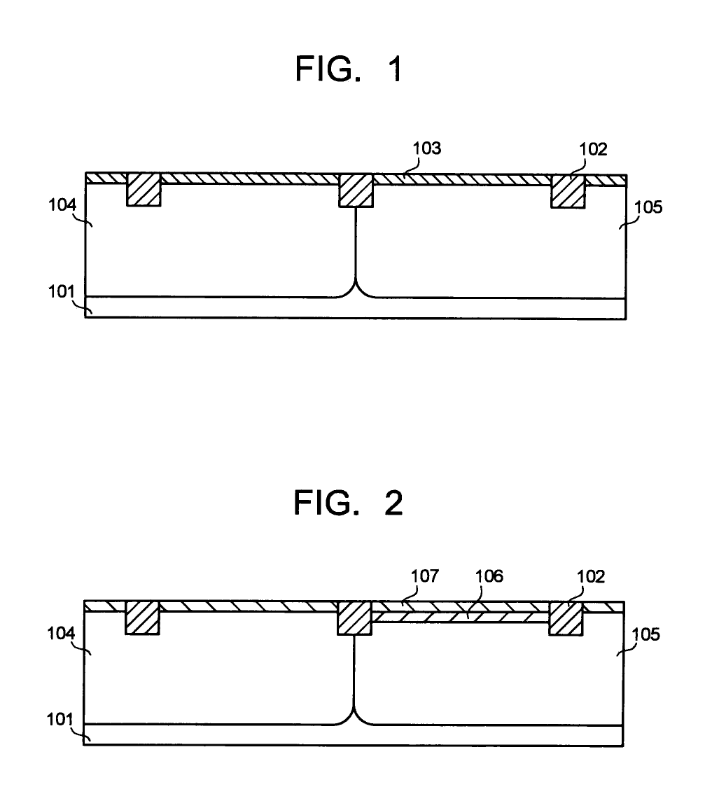

FIGS. 1 to 8 relate to the steps of the manufacturing method of a semiconductor device according to a first embodiment. In this embodiment, a single metal gate transistor will be manufactured.

First of all, as shown in FIG. 1, a semiconductor substrate 101 made of, e.g., silicon is prepared, followed by that an element separation region 102 configured as an STI structure, a sacrifice film 103, an n-type diffusion layer 104 and a p-type diffusion layer 105 are formed at the semiconductor substrate 101. The sacrifice layer 103 is formed so as to cover the n-type diffusion layer 104 and the p-type diffusion layer 105. The n-type diffusion layer 104 is to constitute a PMOSFET and the p-type diffusion layer 105 is to constitute a NMOSFET.

Then, the portion of the sacrifice layer 103 located on the n-type diffusion layer 104 is removed using an NH₄F aqueous solution or a dilute hydrofluoric acid solution via a mask made of resist. Then, the epitaxial growth of SiGe is selectively conducted for the n-type diffusion layer 104 to form a channel SiGe layer 106 thereon and subsequently deposit silicon material. Then, the portion of the sacrifice layer 103 located on the p-type diffusion layer 105 is removed using an NH₄F aqueous solution or a dilute hydrofluoric acid solution, and a chemical SiO₂ film (silicon oxide film) 107 are formed on both of the n-type diffusion layer 104 and the p-type diffusion layer 105 (FIG. 2).

The silicon oxide film 107 is formed so as to prevent the formation of interface state and lastly, can prevent (enhance) the electric characteristics of the intended transistor such as the mobility thereof.

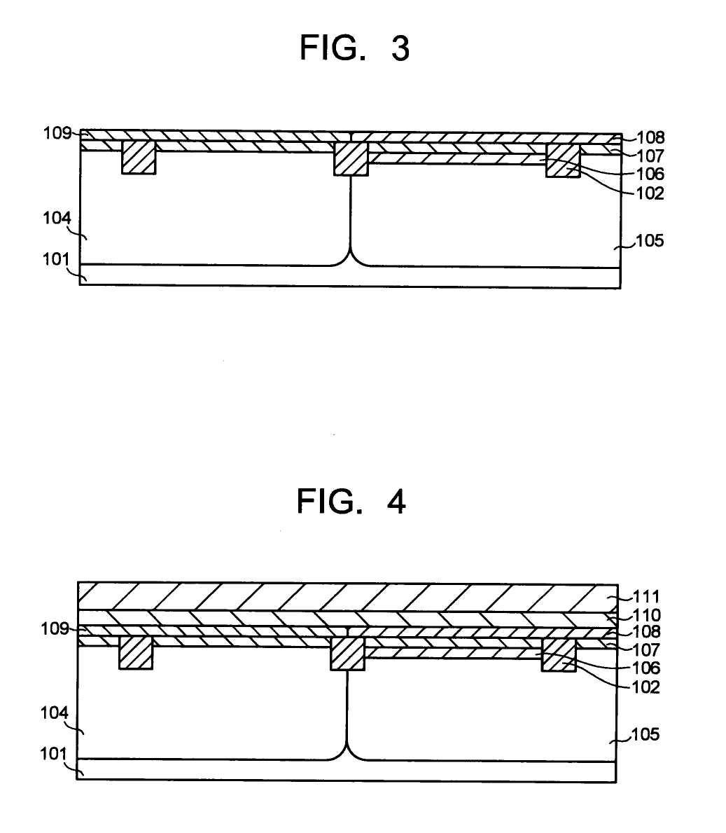

As shown in FIG. 3, then, an Al₂O₃ film 108 is formed over the silicon oxide film 107 by means of ALD method, followed by that the portion of the Al₂O₃ film 108 located above the p-type diffusion layer 105 is etched and removed using a resist mask to expose the portion of the silicon oxide film 107 located above the p-type diffusion layer 105. Then, after the resist mask is peeled off, an La₂O₃ film 109 is deposited over the portion of the silicon oxide film 107 located on the p-type diffusion layer 105 and the remaining portion of the Al₂O₃ film 108 located above the n-type diffusion layer 104 by means of PVD method. Then, the portion of the La₂O₃ film 109 located above the n-type diffusion layer 104 is etched and removed using a resist mask.

After the resist mask is peeled off, as shown in FIG. 4, a HfSiO film (hafnium silicon oxide film) with a thickness of 2.5 nm is formed over the remaining portion of the Al₂O₃ film 108 located above the n-type diffusion layer 104 and the remaining portion of the La₂O₃ film 109 located above the p-type diffusion layer 105 by means of MOCVD method. Then, the HfSiO film is treated under an atmosphere of nitrogen plasma and thermally treated so as to be converted into a HfSiON film (hafnium silicon oxynitride film) 110. The HfSiON film 110 functions as a gate insulating film. It is desirable that the gate insulating film contains Hf element because of the enhancement of dielectric constant (insulating property), so that a HfO₂ film and HfSiO film in addition to the HfSiON film are exemplified. Then, a TiN film (titanium nitride film) 111 constituting a gate electrode layer is formed by means of PVD method.

If the gate insulating film contains Si elements, Ge elements cannot be diffused into the gate insulating layer, so that Ge inclusions can be formed at the interface between the metallic film of the gate electrode layer and the gate insulating film under good controllability, as will be described hereinafter.

Moreover, if the gate insulating film contains N elements in addition to the Si elements, the barrier property of the gate insulating film is much enhanced so that the Ge elements cannot be diffused into the gate insulating film effectively. As a result, the Ge inclusions can be formed at the interface between the metallic film of the gate electrode layer and the gate insulating film under good controllability, as described above.

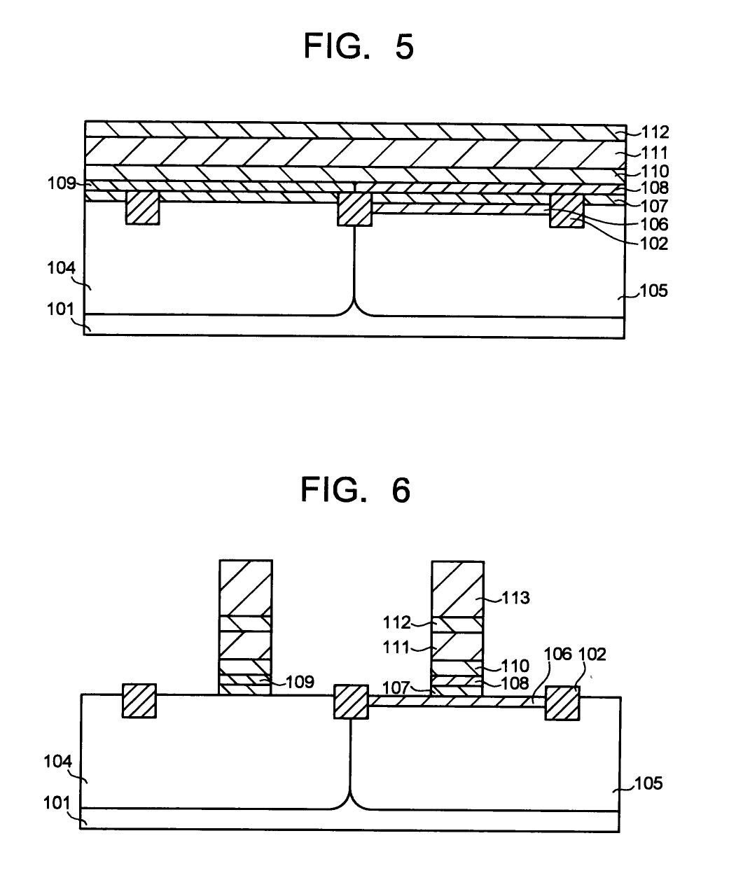

As shown in FIG. 5, then, a polycrystalline Ge film 112 is deposited over the TiN film 111 by means of PVD method or CVD method using germane.

As shown in FIG. 6, then, a polysilicon film (silicon-containing film) 113 is deposited, followed by that the polysilicon film 113, the Ge film 112, the TiN film 111, the HfSiON film 110, the Al₂O₃ film 108 remaining in the n-type diffusion layer 104, the La₂O₃ film 109 remaining in the p-type diffusion layer 105 and the silicon oxide film 107 are etched by means of RIE process.

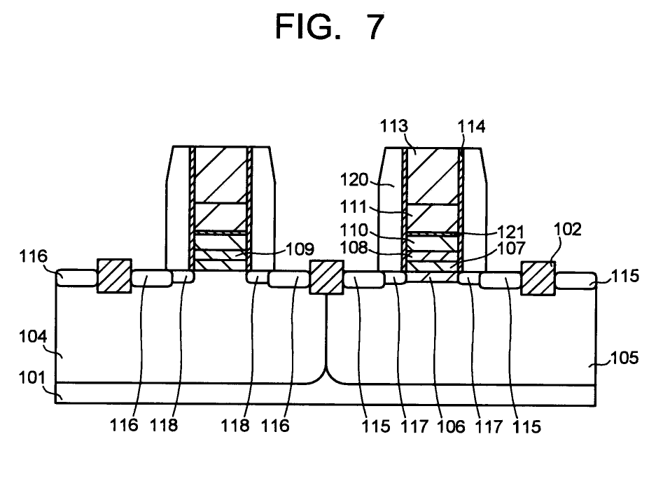

As shown in FIG. 7, then, a silicon oxide film or a silicon nitride film is formed over the thus etched structure by means of CVD method, and etched by means of RIE method to form offset spacers 114. Then, side wall spacers 120 made of a silicon oxide film or a silicon nitride film are formed by means of CVD method and RIE method. Then, boron ions are injected into the n-type diffusion layer 104 via a resist mask, and similarly, phosphorous ions or arsenic ions are injected into the p-type diffusion layer 105 via a resist mask. Then, thermal treatment is conducted to form the p-type source/drain diffusion layer 115 and the n-type source/drain diffusion layer 116.

In this case, the Ge atoms of the Ge film 112 located on the TiN film 111 are diffused up to the interface between the TiN film 111 and the HfSiON film through the TiN film 111 to form Ge inclusions thereat. The Ge inclusions are not always required to be layered, but may be formed such that the Ge atoms are coupled with the metallic atoms of the TiN film 111.

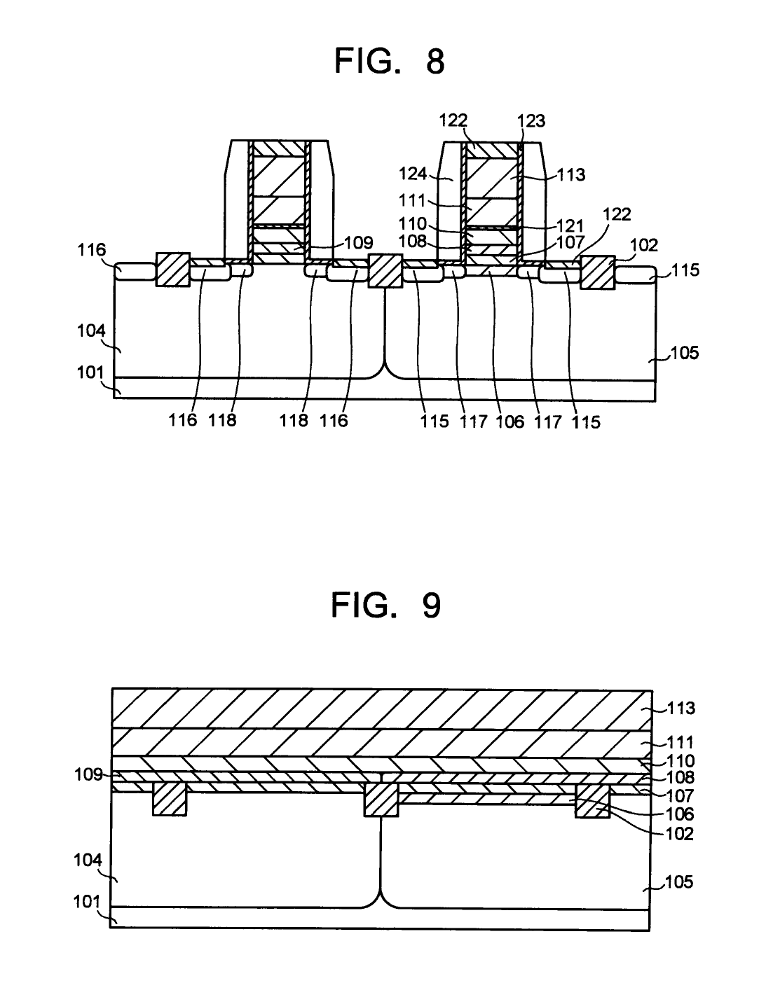

As shown in FIG. 8, then, after the side wall spacers 120 are removed, boron ions are injected into the n-type diffusion layer 104 via a resist mask, and similarly, phosphorous ions or arsenic ions are injected into the p-type diffusion layer 105 via a resist mask. Then, thermal treatment is conducted to form p-type extension regions 117 and n-type extension regions 118. Thereafter, two-layered side wall spacers, each spacer being made of an SiO₂ film 123 and an SiN film 124, are formed by means of CVD method and RIE method. Then, silicide films 122 are formed on the respective source/drain regions and the respective polysilicon films 113 in self-alignment. As a result, the intended single metal gate transistor can be manufactured.

In this embodiment, the TiN film 111 constitutes the gate electrode (layer).

Not particularly shown, if interlayer insulating films, contact holes, wirings and the like are formed while the contact holes are embedded, a semiconductor integrated circuit may be formed.

In this embodiment, the Ge inclusion 121 is formed between the gate insulating film made of the HfSiON film 110 and the gate electrode made of the TiN film 111, the polysilicon film 113 and the silicide film 122 per transistor. Therefore, the effective work function of the gate electrode can be set to the state in the vicinity of the mid-gap state of the Si bandgap.

Moreover, since the effective work function of the n-type diffusion layer 104, that is, the NMOSFET can be decreased by about 0.5 eV due to the formation of the La₂O₃ film 109, the effective work function of the NMOSFET can be set to the state in the vicinity of the Si conduction band edge (4.05 eV). Furthermore, the effective work function of the p-type diffusion layer 105, that is, the PMOSFET can be set to the state in the vicinity of the Si valence band edge (5.17 eV) due to the formation of the channel SiGe film 106 and the Al₂O₃ film 108. As a result, the threshold voltage of each transistor can be sufficiently and stably reduced.

The reason why the effective work function of the gate electrode can be set to the state in the vicinity of the mid-gap state of the Si bandgap through the existence of the Ge inclusion can be considered as follows. Namely, as apparent from the manufacturing method as described above, the gate electrode contains the polysilicon film 113 for the formation of the silicide film 122 in addition to the TiN film 111. However, the constituent elements of the polysilicon film 113 are diffused to the interface between the TiN film 111 and the HfSiON film 110 by the thermal treatment for the formation of the source/drain diffusion layer, for example.

In this embodiment, on the other hand, since the Ge inclusions exist at the interface between the TiN film 111 and the HfSiON film 110, the constituent elements of the polysilicon film 113 are unlikely to be diffused to the interface therebetween. As a result, it is considered that the effective work function of the gate electrode can be stably set to the state in the vicinity of the mid-gap state.

In other words, the fluctuation of the effective work function of the gate electrode from the mid-gap state may be originated from the diffusion of the constituent elements (i.e, silicon elements) of the polysilicon film 113 to the interface between the TiN film 111 and the HfSiON film 110. In this point of view, in this embodiment, it may be considered the effective work function of the gate electrode can be stably set to the state in the vicinity of the mid-gap state because the diffusion of the silicon elements can be suppressed due to the existence of the Ge inclusions 121.

In this embodiment, the metallic film of the gate electrode is made of the TiN film, but may be made of another film such as a tantalum carbide (TaC) film, a tantalum nitride (TaN) film and a tantalum silicon nitride (TaSiN) in order to exhibit the same function/effect as described above.

It is desired that the Ge elements diffused from the Ge layer 112 exist in the TiN film 111 when the Ge inclusions are formed. In this case, the effective work function of the gate electrode can be much stably set to the state in the vicinity of the mid-gap state because the diffusion of the silicon elements of the polysilicon film 113 is suppressed at the TiN film 111 in addition to the Ge inclusions 121.

### Second Embodiment

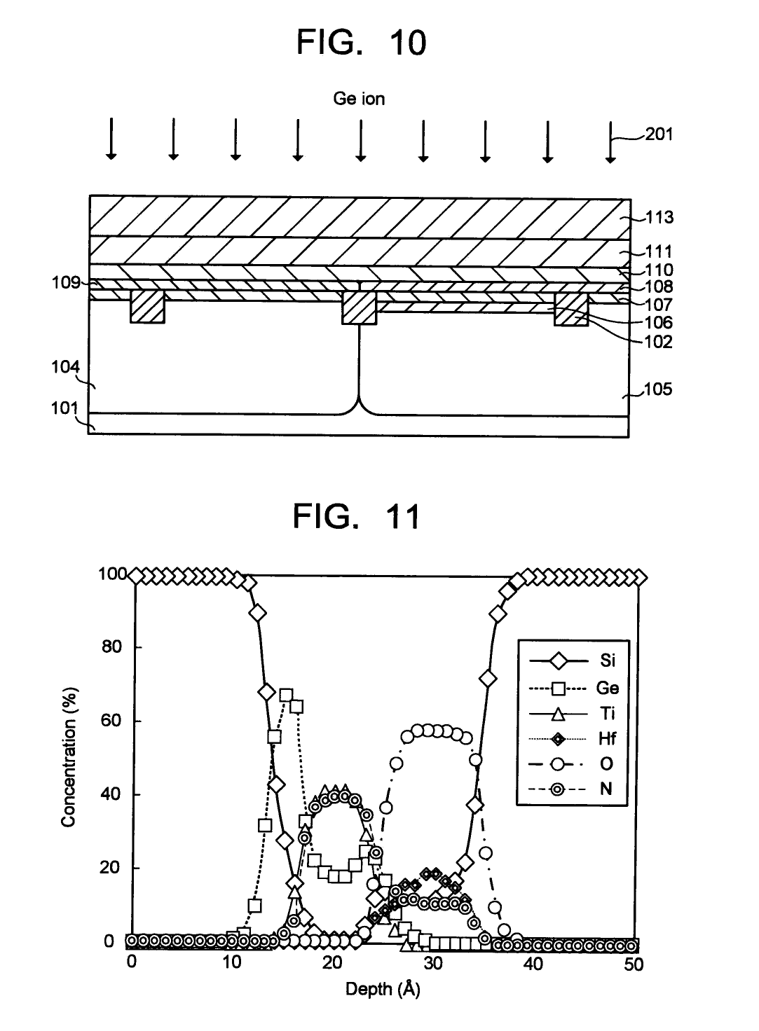

FIGS. 9 to 10 relate to the steps of the manufacturing method of a semiconductor device according to a second embodiment. In this embodiment, a single metal gate transistor will be also manufactured. Like or corresponding components are designated by the same references through the first embodiment and the second embodiment.

First of all, according to the steps shown in FIGS. 1 to 4 in the first embodiment, the element separation region 102 configured as an STI structure, the sacrifice film 103, the n-type diffusion layer 104 and the p-type diffusion layer 105 are formed at the semiconductor substrate 101. The sacrifice layer 103 is formed so as to cover the n-type diffusion layer 104 and the p-type diffusion layer 105. Then, the portion of the sacrifice layer 103 located on the n-type diffusion layer 104 is removed using an NH₄F aqueous solution or a dilute hydrofluoric acid solution via a mask made of resist. Then, the epitaxial growth of SiGe is selectively conducted for the n-type diffusion layer 104 to form the channel SiGe layer 106 thereon and subsequently deposit silicon material.

Then, the portion of the sacrifice layer 103 located on the p-type diffusion layer 105 is removed using an NH₄F aqueous solution or a dilute hydrofluoric acid solution, and a chemical SiO₂ film (silicon oxide film) 107 are formed on both of the n-type diffusion layer 104 and the p-type diffusion layer 105. Then, the Al₂O₃ film 108 is formed over the silicon oxide film 107 by means of ALD method, followed by that the portion of the Al₂O₃ film 108 located above the p-type diffusion layer 105 is etched and removed using a resist mask to expose the portion of the silicon oxide film 107 located on the p-type diffusion layer 105. Then, after the resist mask is peeled off, the La₂O₃ film 109 is deposited over the portion of the silicon oxide film 107 located on the p-type diffusion layer 105 and the remaining portion of the Al₂O₃ film 108 located above the n-type diffusion layer 104 by means of PVD method. Then, the portion of the La₂O₃ film 109 located above the n-type diffusion layer 104 is etched and removed using a resist mask.

After the resist mask is peeled off, as shown in FIG. 4, the HfSiO film (hafnium silicon oxide film) with a thickness of 2.5 nm is formed over the remaining portion of the Al₂O₃ film 108 located above the n-type diffusion layer 104 and the remaining portion of the La₂O₃ film 109 located above the p-type diffusion layer 105 by means of MOCVD method. Then, the HfSiO film is treated under an atmosphere of nitrogen plasma and thermally treated so as to be converted into the HfSiON film (hafnium silicon oxynitride film) 110. The HfSiON film 110 functions as a gate insulating film. Then, the TiN film (titanium nitride film) 111 constituting a gate electrode layer is formed by means of PVD method.

As shown in FIG. 9, then, the polysilicon film 113 is formed over the TiN film 111 and Ge ions are injected into the polysilicon film 113 from above, thereby forming the Ge inclusions at the interface between the TiN film 111 and the HfSiON film (hafnium silicon oxynitride film) 110. The Ge inclusions are not always required to be layered, but may be formed such that the Ge atoms are coupled with the metallic atoms of the TiN film 111.

Then, according to the steps shown in FIGS. 6 to 8 relating to the first embodiment, the polysilicon film 113, the TiN film 111, the Ge inclusions 121, the HfSiON film 110, the Al₂O₃ film 108 remaining in the n-type diffusion layer 104, the La₂O₃ film 109 remaining in the p-type diffusion layer 105 and the silicon oxide film 107 are etched by means of RIE process, and then, the spacers 114 and 120 are formed so that the p-type source/drain regions 115 and the n-type source/drain regions 116.

Then, after the spacers 120 are removed, the p-type extension regions 117 and the n-type extension regions 118 are formed. Then, after the side wall spacers are formed, the silicide films 122 are formed on the respective source/drain regions and the respective polysilicon films 113 in self-alignment. As a result, the intended single metal gate transistor can be manufactured.

In this embodiment, the TiN film 111 constitutes the gate electrode (layer).

In this embodiment, the Ge inclusion 121 is formed between the gate insulating film made of the HfSiON film 110 and the gate electrode made of the TiN film 111, the polysilicon film 113 and the silicide film 122 per transistor. Therefore, the effective work function of the gate electrode can be set to the state in the vicinity of the mid-gap state of the Si bandgap.

Moreover, since the effective work function of the n-type diffusion layer 104, that is, the NMOSFET can be decreased by about 0.5 eV due to the formation of the La₂O₃ film 109, the effective work function of the NMOSFET can be set to the state in the vicinity of the Si conduction band edge (4.05 eV). Furthermore, the effective work function of the p-type diffusion layer 105, that is, the PMOSFET can be set to the state in the vicinity of the Si valence band edge (5.17 eV) due to the formation of the channel SiGe film 106 and the Al₂O₃ film 108. As a result, the threshold voltage of each transistor can be sufficiently and stably reduced.

The reason why the effective work function of the gate electrode can be set to the state in the vicinity of the mid-gap state of the Si bandgap through the existence of the Ge inclusion can be considered as in the first embodiment.

In this embodiment, the metallic film of the gate electrode is made of the TiN film, but may be made of another film such as a tantalum carbide (TaC) film, a tantalum nitride (TaN) film and a tantalum silicon nitride (TaSiN) in order to exhibit the same function/effect as described above.

It is also desired that the injected Ge ions exist in the TiN film 111 when the Ge inclusions are formed. In this case, the effective work function of the gate electrode can be much stably set to the state in the vicinity of the mid-gap state. This is because the diffusion of the silicon elements of the polysilicon film 113 is suppressed at the TiN film 111 in addition to the Ge inclusion 121 as in the first embodiment.

### Third Embodiment

The RBS (Rutherford back scattering) measurement was conducted for one of the transistor structures. The measurement result was shown in FIG. 11. As apparent from FIG. 11, it is turned out that the Ge elements are diffused into the TiN film 111 and segregated at the interface between the TiN film 111 and the HfSiON film 110 to form the Ge inclusions.

Although the present invention was described in detail with reference to the above examples, this invention is not limited to the above disclosure and every kind of variation and modification may be made without departing from the scope of the present invention.

For example, in the embodiments, after the source/drain regions are formed, the side wall spacers are removed to form the extension diffusion layers 117 and 118. It may be, however, that after the offset spacers are formed so that the extension regions are formed, the side wall spacers are formed so that the source/drain regions are formed. In this case, the same transistor as shown in the embodiments can be manufactured.

What is claimed is:

1. A semiconductor device, comprising:
a semiconductor substrate containing a p-type diffusion layer and an n-type diffusion layer which are separated by an element separation film;
a gate insulating film formed on or above the p-type diffusion layer and the n-type diffusion layer of the semiconductor substrate, respectively;
a gate electrode containing a metallic film and formed on the gate insulating film;
a Ge inclusion formed at an interface between the gate insulating film and the metallic film; and
a silicon-containing layer formed on the metallic film.

2. The semiconductor device as set forth in claim 1,
wherein the gate insulating film contain elemental Si.

3. The semiconductor device as set forth in claim 2,
wherein the gate insulating film contain elemental N.

4. The semiconductor device as set forth in claim 1,
wherein the gate insulating film is made of at least one selected from the group consisting of HfSiON, HfO₂, and HfSiO.

5. The semiconductor device as set forth in claim 1,
wherein the metallic layer contain elemental Ge.

6. The semiconductor device as set forth in claim 1,
wherein the metallic layer is made of at least one selected from the group consisting of TiN, TaC, TaN and TaSiN.

7. The semiconductor device as set forth in claim 1, further comprising,
a silicide film formed on the silicon-containing layer such that the metallic film, the silicon-containing layer and the silicide film constitute the gate electrode.

8. A method for manufacturing a semiconductor device, comprising:
forming an element separation film in a semiconductor substrate such that a p-type diffusion layer is formed at one side of the semiconductor substrate from the element separation film thereof and an n-type diffusion layer is formed at the other side of the semiconductor substrate from the element separation film thereof;
forming a gate insulating film on or above the p-type diffusion layer and the n-type diffusion layer of the semiconductor substrate, respectively;
forming a gate electrode containing a metallic film on the gate insulating film;
forming a Ge layer on the metallic film such that elemental Ge of the Ge layer is diffused to an interface between the gate insulating film and the metallic film through thermal treatment to form a Ge inclusion at the interface therebetween; and
forming a silicon-containing layer on the metallic film.

9. The manufacturing method as set forth in claim 8,
wherein elemental Si is contained in the gate insulating film.

10. The manufacturing method as set forth in claim 9,
wherein elemental N is contained in the gate insulating film.

11. The manufacturing method as set forth in claim 8,
wherein the gate insulating film is made of at least one selected from the group consisting of HfSiON, HfO₂, and HfSiO.

12. The manufacturing method as set forth in claim 8,
wherein elemental Ge is contained in the metallic layer.

13. The manufacturing method as set forth in claim 8,
wherein the metallic layer is made of at least one selected from the group consisting of TiN, TaC, TaN and TaSiN.

14. A method for manufacturing a semiconductor device, comprising:
forming an element separation film in a semiconductor substrate such that a p-type diffusion layer is formed at one side of the semiconductor substrate from the element separation film thereof and an n-type diffusion layer is formed at the other side of the semiconductor substrate from the element separation film thereof;
forming a gate insulating film on or above the p-type diffusion layer and the n-type diffusion layer of the semiconductor substrate, respectively;
forming a gate electrode containing a metallic film on the gate insulating film;
forming a polysilicon layer on the metallic layer;
injecting Ge ions into the polysilicon layer such that a Ge inclusion is formed at an interface between the gate insulating film and the metallic film; and
forming a silicon-containing layer on the metallic film.

15. The manufacturing method as set forth in claim 14,
wherein elemental Si is contained in the gate insulating film.

16. The manufacturing method as set forth in claim 15,
wherein elemental N is contained in the gate insulating film.

17. The manufacturing method as set forth in claim 14,
wherein the gate insulating film is made of at least one selected from the group consisting of HfSiON, HfO₂, and HfSiO.

18. The manufacturing method as set forth in claim 14,
wherein the Ge ions are contained in the metallic layer.

19. The manufacturing method as set forth in claim 14,
wherein the metallic layer is made of at least one selected from the group consisting of TiN, TaC, TaN and TaSiN.
